(19) United States
(12) Patent Application Publication
(10) Pub. No.: US 2015/0234005 A1
(43) Pub. Date: Aug. 20, 2015

(54) MEMORY PACKAGE TEST JIG HAVING HARSH CONDITION CREATING STRUCTURE

(71) Applicant: SOLID MECA CO., LTD., Gyeonggi-do (KR)

(72) Inventor: Tae Wan KIM, Gyeonggi-do (KR)

(73) Assignee: SOLID MECA CO., LTD., Gyeonggi-do (KR)

(21) Appl. No.: 14/283,665

(22) Filed: May 21, 2014

(30) Foreign Application Priority Data
Feb. 18, 2014 (KR) 10-2014-0018645

(51) Int. Cl. G01R 31/28

(52) U.S. Cl. CPC G01R 31/2891; G01R 31/2889

(57) ABSTRACT

Disclosed herein is a memory package test jig having a harsh condition creating structure. The memory package test jig includes an upper jig which has package seating holes into which memory packages are seated, a lower jig which fixes a socket board in a place between it and the upper jig, a pusher housing which is hinged to the upper jig, a lift panel which is installed below the pusher housing so as to be vertically movable, a pressing panel which vertically moves the lift panel, a lift means which is provided to embody the vertical movement of the lift panel, a pusher block which presses the memory packages, a harsh-thermal-environment creating unit which creates harsh thermal conditions, a cooling unit which conducts a cooling operation when the harsh-thermal-environment creating unit generates or absorbs heat, and a lift lever which linearly move the pressing panel leftwards or rightwards.

### BACKGROUND OF THE INVENTION

1. Field of the Invention

The present invention relates generally to memory package test jigs having harsh condition creating structures and, more particularly, to a memory package test jig having a harsh condition creating structure which can create harsh thermal limit conditions similar to a real use environment of memory packages (e.g., memory chips) which are mounted on various kinds of cards (e.g., graphic cards or sound cards) installed in computers, when testing the memory packages for defects, thus making it possible to obtain more reliable memory packages.

2. Description of the Related Art

Computers are being rapidly enhanced in performance as central processing units (CPUs) develop. Competition continues to push the develop computers, which have faster and are better in performance, and particularly, there is a drive to develop super computers, parallel processing computers and RISCs (reduced instruction set computers). Efforts to enhance the performance of computers are widespread and ongoing.

Generally, computers include a mainboard, and a plurality of slots are formed in the mainboard. Different kinds of expansion cards such as a sound card, a graphic card, etc. are installed in the slots of the mainboard.

Such expansion cards can be selectively installed or replaced with others to satisfy the needs required by users. For instance, if a user wants to optimize a computer for graphics processing work, a high specification graphic card can be installed. A high specification sound card can be installed for music processing work.

Although expansion cards may be installed when computers are produced, they are typically produced separately from production of computers.

Various types and kinds of packages are mounted on expansion cards such that intended functions thereof can be reliably conducted. A solder ball mounting method is mainly used to mount such packages on expansion cards.

The solder ball mounting method refers to BGA (ball grid array) packages. Such packages are a kind of SMD (side mount device), and balls are used in lieu of pins (PGA) or lead (GFP) sides when packages are mounted. According to material, BGAs are classified into flexible BGA (Main PI material), C-BGA (Ceramic) and P-BGA (Plastic, BT).

The above-described BGA packaging technology can reduce the sizes of chips by about 50% of those of the existing chips, whereby the area required to mount chips on boards (mainboards, graphic cards, sound cards, etc.) can be markedly reduced. Given the recent trend of high density integration and a reduction in size, once such packages are mounted on an expansion card, it is almost impossible to remove the packages therefrom.

Therefore, in the conventional techniques, the various packages are tested for defects in such a way that after an expansion card on which the packages have been mounted is connected to a computer, the expansion card is tested for performance.

However, in the case where the packages are tested for defects by the conventional method, if there is a defect in a package, excessive cost loss (costs for mounting, expansion cards, etc.) is caused because only after the packages are mounted on the expansion card can the test be conducted.

To avoid the above-mentioned problems, packages may be tested for performance before they are mounted on expansion cards. However, in this case, although it is possible to test the performance of a package itself, there is no means for determining whether the package is normally operated under real use conditions, that is, in a state in which it is mounted on an expansion card. Therefore, there is a problem in that characteristics of the package that are subject to the influence of a plurality of elements (e.g. adjacent chips, etc.) mounted on the expansion card cannot be checked.

### PRIOR ART DOCUMENT

### Patent Document

(Patent document 1) 1. Korean Patent Registration No. 1177051 (Publication date: Aug. 27, 2012)

(Patent document 2) 1. Korean Patent Application No. 2013-0002582 (Application date: Jan. 9, 2013)

### SUMMARY OF THE INVENTION

Accordingly, the present invention has been made keeping in mind the above problems occurring in the prior art, and an object of the present invention is to provide a memory package test jig having a harsh condition creating structure which can provide harsh thermal limit conditions to a memory package to create an environment similar to a real use environment where the memory package is mounted on an expansion card installed in a computer, thus making it possible to test thermal limit characteristics of the memory package.

Another object of the present invention is to provide a memory package test jig having a harsh condition creating structure which can provide harsh thermal limit conditions to a memory package to create an environment similar to a real use environment where the memory package is mounted on an expansion card installed in a computer, thus making it possible to obtain more reliable memory packages.

In order to accomplish the above object, the present invention provides a memory package test jig having a harsh condition creating structure, comprising: an upper jig with a plurality of package seating holes vertically formed in the upper jig at positions corresponding to respective sockets mounted on a socket board, wherein memory packages are respectively seated into the package seating holes; a lower jig fixing the socket board between the lower jig and the upper jig; a pusher housing hinged at a first end thereof to an upper side of the upper jig such that a second end of the pusher housing is movable upwards or downwards; a lift panel provided below the pusher housing so as to be elastically movable upwards or downwards; a pressing panel provided under the pusher housing so as to be linearly movable to leftwards or rightwards, the pressing panel moving the lift panel upwards or downwards; a lift means provided to enable the upward or downward movement of the lift panel; a pusher block provided below the lift panel, the pusher blocking comprising pushers provided corresponding to the respective package seating holes, the pushers pressing the corresponding memory packages; a harsh-thermal-environment creating unit provided on an upper side of the pusher block, the harsh-thermal-environment creating unit generating or absorbing heat to provide harsh thermal conditions to the memory packages; a cooling unit conducting a cooling operation when the harsh-thermal-environment creating unit generates or absorbs heat; and a lift lever provided to an end of the lift panel, the lift lever rotating leftwards or rightwards so as to linearly move the pressing panel leftwards or rightwards.

The lift means may include: a plurality of rollers rotatably provided in the pressing panel in such a way that a portion of each roller is protruded from a side of the pressing panel; and a plurality of lift guides, each lift guide comprising: an inclined side formed on an upper side of the lift panel and a horizontal side formed on a top of the inclined side corresponding to a range of movement of the roller corresponding to the linear left or right movement of the pressing panel.

When the rollers are moved upwards to the horizontal sides along the inclined sides of the lift guides by linearly moving the pressing panel in one direction, the lift panel may be pressured by the rollers and moved downwards, and when the rollers are moved downwards from the horizontal sides of the lift guides to lowermost portions of the lift guides along the inclined sides by linearly moving the pressing panel in the other direction, the lift panel may be released from the pressure of the rollers and moved upwards.

The harsh-thermal-environment creating unit may include: an element protection block having a shape corresponding to the pusher block, the element protection block comprising a plurality of element seating parts configured to correspond to the respective pushers; and a plurality of peltier elements provided in the respective element seating parts of the element protection block, the peltier elements generating or absorbing heat by voltage applied thereto so as to provide harsh thermal conditions of a high or low temperature to the corresponding memory packages through the pusher block and the pushers.

The voltage applied to the peltier elements of the harsh-thermal-environment creating unit may be positive voltage or negative voltage, whereby one side of the peltier element may generate or absorb heat, thus providing harsh thermal conditions of a high or low temperature to the corresponding memory package through the pusher block and the pusher.

The harsh thermal conditions created by the harsh-thermal-environment creating unit may comprise low-temperature harsh environment conditions ranging in temperature from −30° C. to 5° C., and high-temperature harsh environment conditions ranging in temperature from 60° C. to 130° C.

The cooling unit may include: a water cooling block provided above the element protection block with the peltier elements seated on the respective element seating parts of the element protection block, the water cooling block having on an upper side thereof a cooling water flow passage along which cooling water flows; a watertight cover covering the upper side of the water cooling block to prevent the cooling water flowing along the cooling water flow passage from leaking; and a cooling water inlet valve and a cooling water outlet valve provided to an upper side of the watertight cover so that cooling water supplied from a cooling water supply source is drawn into an inlet of the cooling water flow passage through the cooling water inlet valve, or from an outlet of the cooling water flow passage through the cooling water outlet valve.

The water cooling block may be fastened to a lower side of the lift panel with the watertight cover installed on the upper side of the water cooling block.

The cooling water inlet valve and the cooling water outlet valve of the cooling unit may be vertically provided on the upper side of the watertight cover corresponding to the inlet and the outlet of the cooling water flow passage in such a way that the cooling water inlet valve and the cooling water outlet valve are exposed from the upper side of the pusher housing through a through hole, the through hole being vertically formed in the pusher housing corresponding to the cooling water inlet valve and the cooling water outlet valve.

The memory package test jig may further include a finishing cover disposed under the pusher block and coupled to a lower end of the pusher housing, the finishing cover having therein a pusher passing opening through which the pushers pass upwards or downwards.

The memory package test jig may further include a cooling fan provided to the upper side of the upper jig so that while the memory packages are tested for defects through the electrical connection between the memory packages and to the corresponding sockets mounted on the socket board fixed between the upper jig and the lower jig, the cooling fan discharges heat generated from the socket board to the outside, thus preventing the socket board from overheating.

The memory package test jig may further include a housing-side shock absorber elastically provided under a lower side of the pusher housing, the housing-side shock absorber absorbing shock generated when the pusher housing rotates downwards and a lower side thereof comes into contact with the upper side of the upper jig and while the close contact between the pusher housing and the upper jig is maintained by a retaining hook provided to an end of the pusher housing.

The memory package test jig may further include a jig-side shock absorber elastically provided to the upper side of the upper jig, the jig-side shock absorber absorbing shock generated when the pusher housing rotates downwards and a lower side thereof comes into contact with the upper side of the upper jig and while the close contact between the pusher housing and the upper jig is maintained by a retaining hook provided to an end of the pusher housing.

The memory package test jig may further include a dry air supply means supplying dry air to the package seating holes to prevent dew condensation from being caused by a temperature difference when the peltier elements generate or absorb heat.

The dry air supply means may include: a plurality of dry air supply passages horizontally formed in a side of the upper jig to predetermined depths adjacent to the package seating holes, each of the dry air supply passage being open downwards; and a dry air supply valve coupled to an inlet of each of the dry air supply passages so that dry air from a dry air supply source is supplied into a space adjacent to the corresponding package seating hole between a lower side of the upper jig and an upper side of the socket board.

A memory package test jig according to the present invention can create harsh thermal conditions similar to a real use environment where the memory package is mounted on an expansion card installed in a computer, whereby the thermal limit characteristics of the memory package can be tested, thus making it possible to obtain more reliable memory packages.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exploded perspective view illustrating a memory package test jig having a harsh condition creating structure according to the present invention;

FIG. 2 is an exploded perspective view illustrating the harsh condition creating structure of the memory package test jig according to the present invention;

FIG. 3 is a sectional view illustrating a dry air supply means of the memory package test jig according to the present invention;

FIGS. 4A and 4B are exploded perspective views respectively illustrating a pressing panel and a lift panel of the memory package test jig according to the present invention;

FIG. 5 is a perspective view showing the assembled memory package test jig according to the present invention;

FIGS. 6A and 6B are plan views showing left or right linear movement of the pressing panel that results from manipulating a lift lever of the memory package test jig according to the present invention;

FIGS. 7A and 7B are sectional views showing left or right linear movement of the pressing panel and upward or downward movement of the lift panel that result from manipulating the lift lever of the memory package test jig according to the present invention; and

FIGS. 8A and 8B are sectional views showing a process of testing a memory package for defects using the memory package test jig according to the present invention.

### DESCRIPTION OF THE PREFERRED EMBODIMENTS

Hereinafter, a preferred embodiment of the present invention will be described in detail with reference to the attached drawings.

Reference now should be made to the drawings, in which the same reference numerals are used throughout the different drawings to designate the same or similar components.

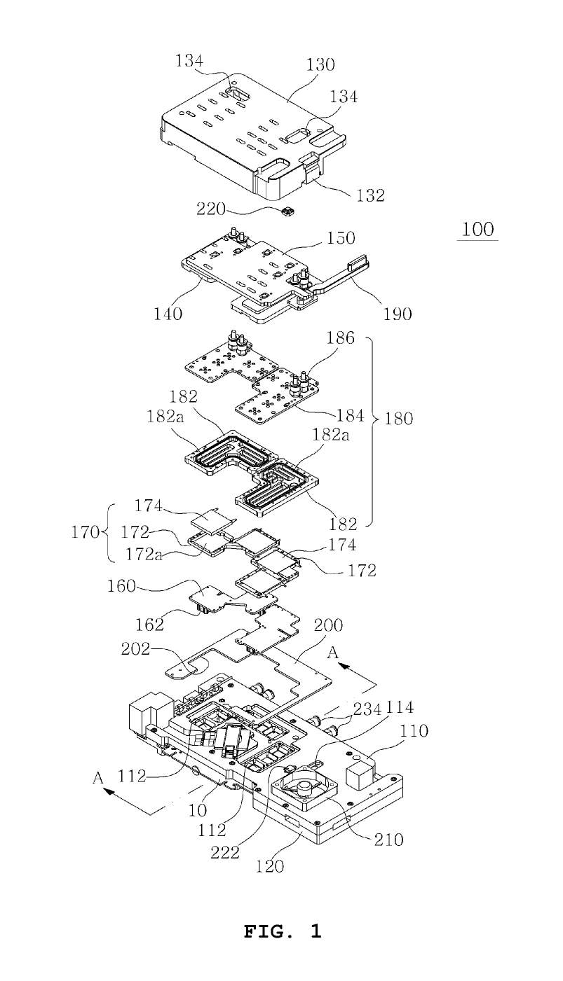

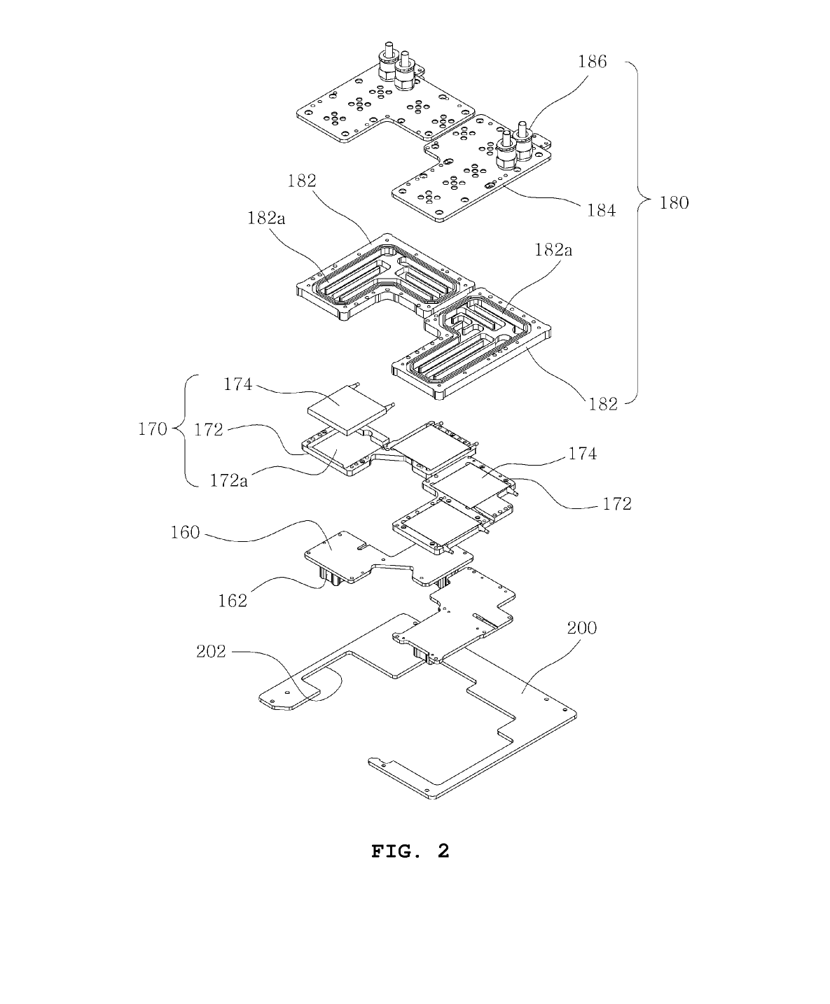

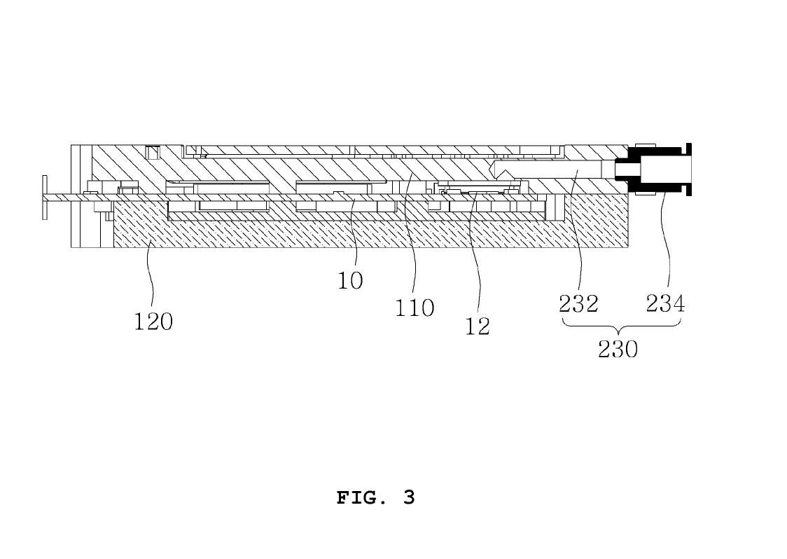

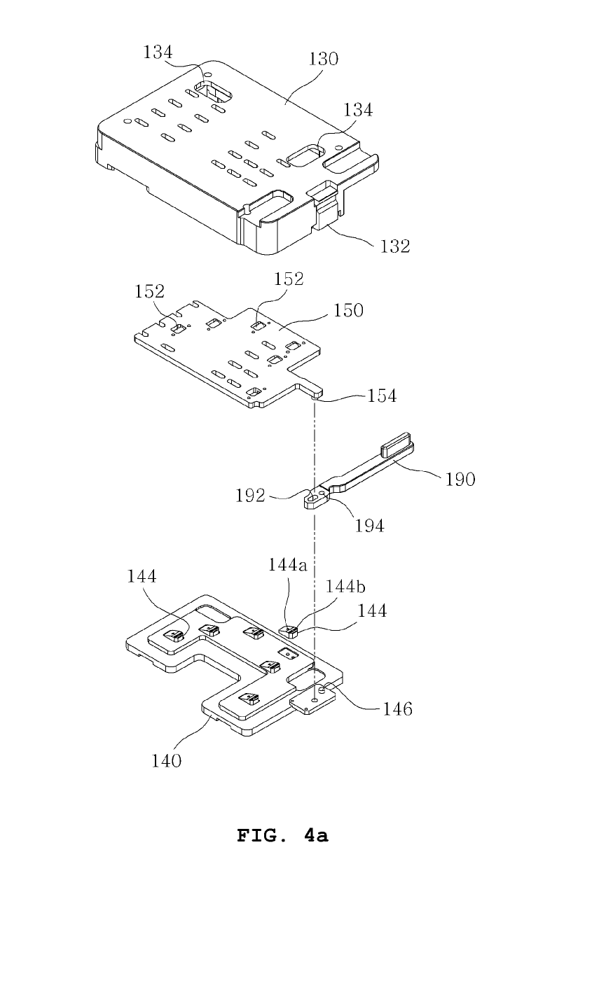

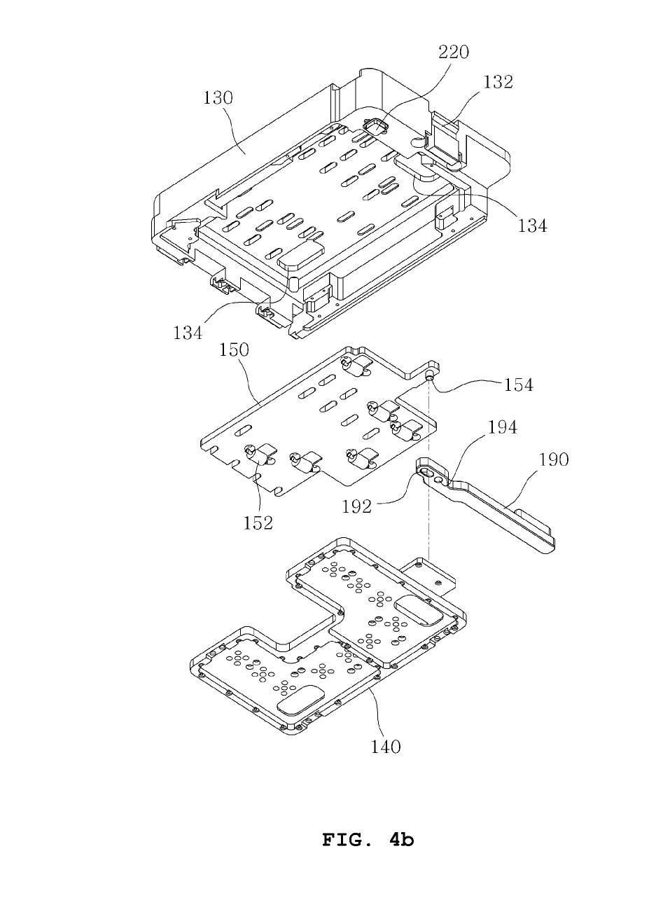

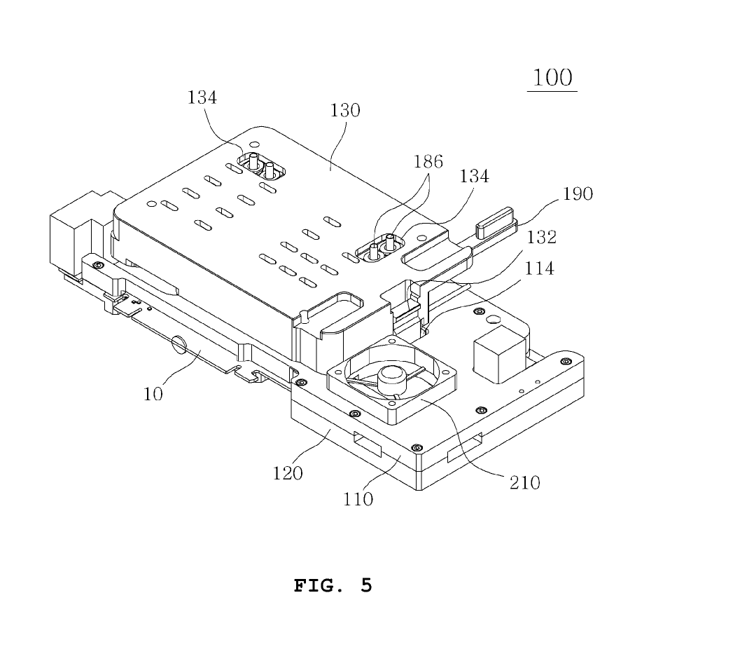

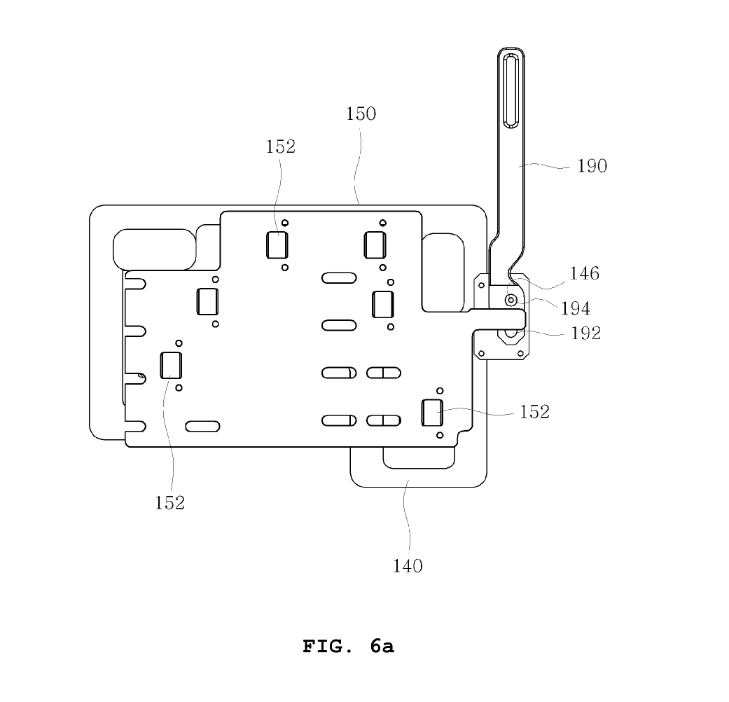

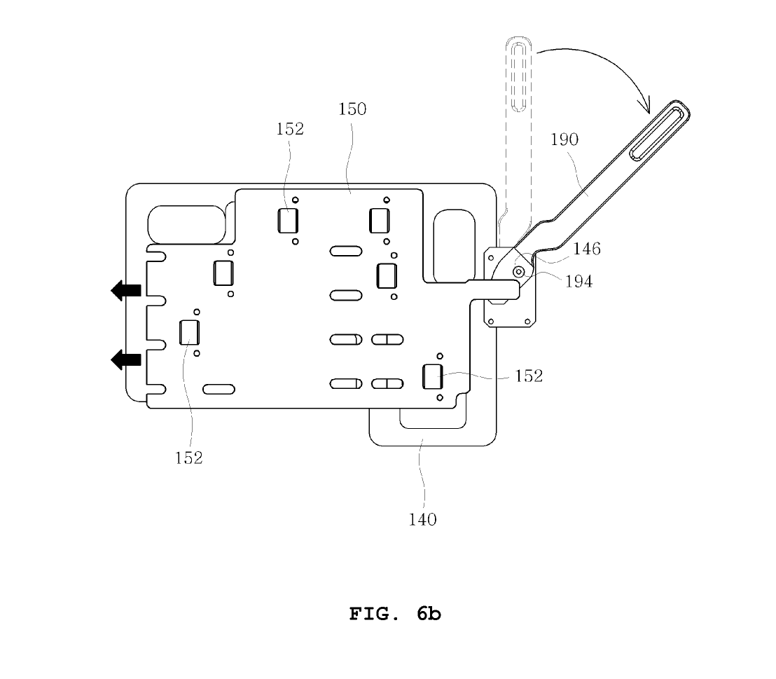

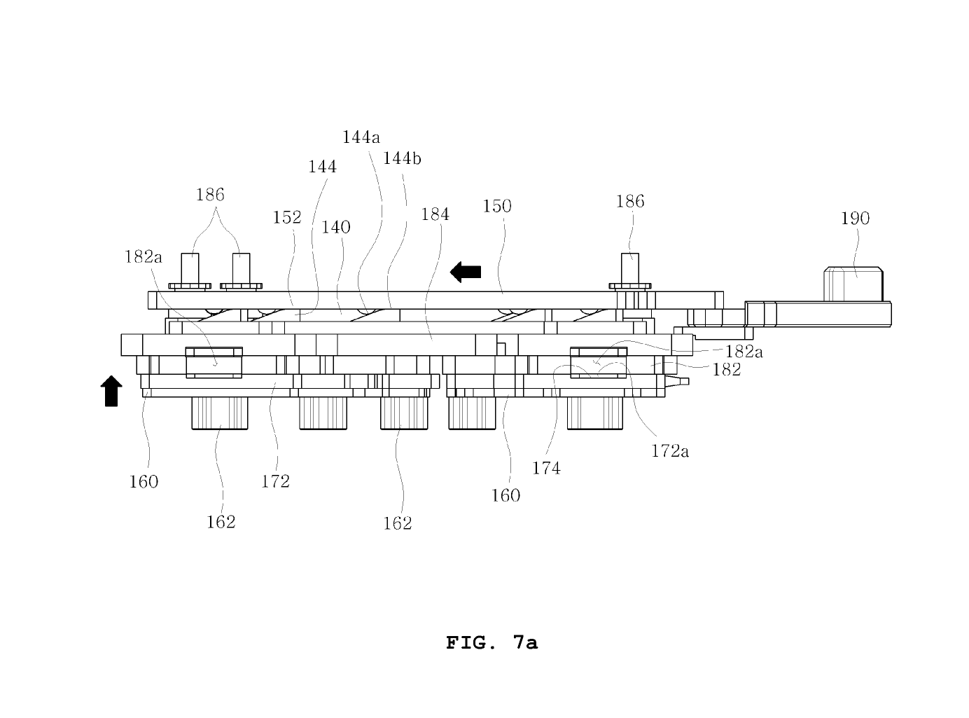

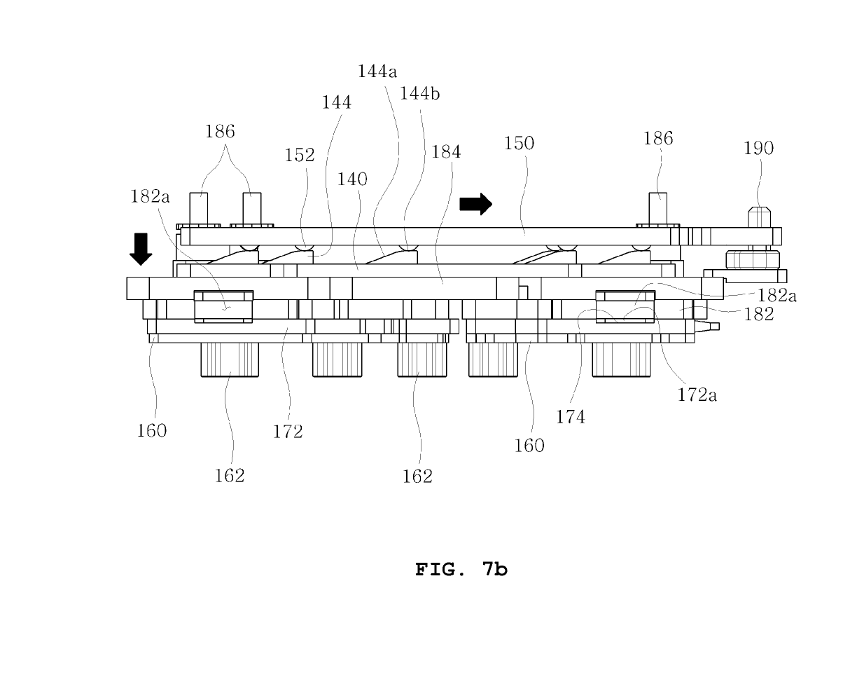

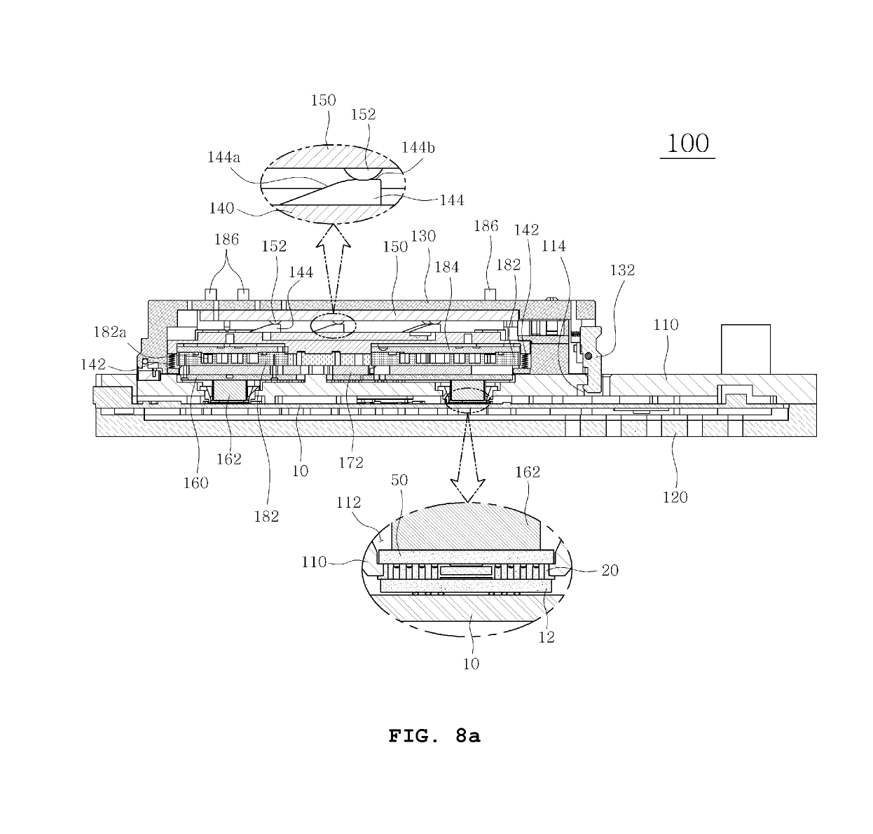

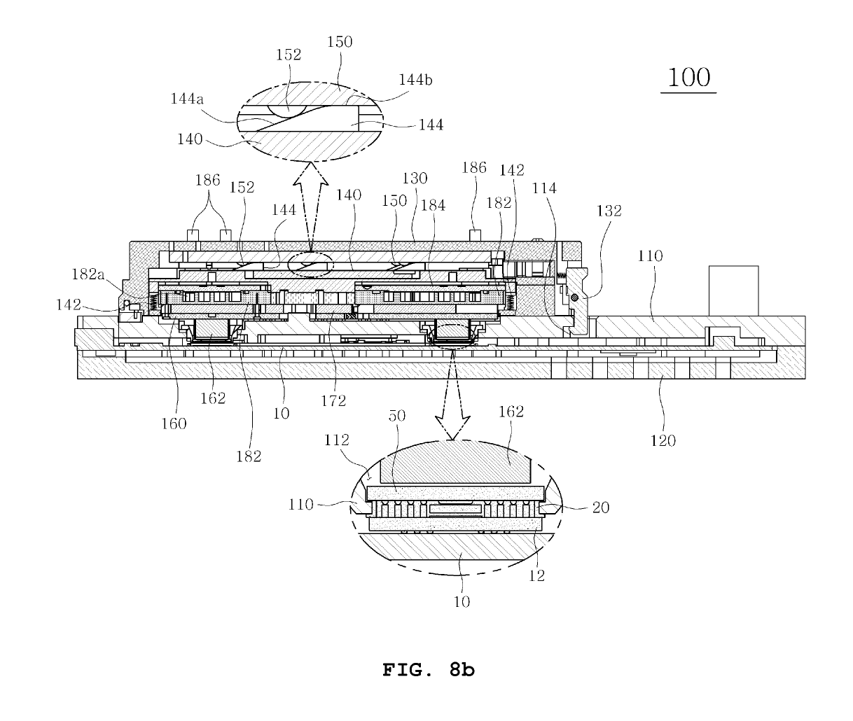

FIG. 1 is an exploded perspective view illustrating a memory package test jig having a harsh condition creating structure according to the present invention, FIG. 2 is an exploded perspective view illustrating the harsh condition creating structure of the memory package test jig according to the present invention, FIG. 3 is a sectional view illustrating a dry air supply means of the memory package test jig according to the present invention, FIGS. 4A and 4B are exploded perspective views respectively illustrating a pressing panel and a lift panel of the memory package test jig according to the present invention, FIG. 5 is a perspective view showing the assembled memory package test jig according to the present invention, FIGS. 6A and 6B are plan views showing left or right linear movement of the pressing panel that results from manipulating a lift lever of the memory package test jig according to the present invention, FIGS. 7A and 7B are sectional views showing left or right linear movement of the pressing panel and upward or downward movement of the lift panel that result from manipulating the lift lever of the memory package test jig according to the present invention, and FIGS. 8A and 8B are sectional views showing a process of testing a memory package for defects using the memory package test jig according to the present invention.

As shown in FIG. 1 through FIG. 8, the memory package test jig according to the present invention includes an upper jig 110, a lower jig 120, a pusher housing 130, a lift panel 140, a pressing panel 150, a lift means, a pusher block 160, a harsh-thermal-environment creating unit 170, a cooling unit 180 and a lift lever 190. The upper jig 110 has package seating holes 112 which are vertically formed in the upper jig 110 at positions corresponding to respective sockets 12 mounted on a socket board 10. Memory packages 50 are respectively seated into the package seating holes 112. The lower jig 120 fixes the socket board 10 in a place between it and the upper jig 110. The pusher housing 130 is hinged at a first end thereof to a first end of an upper portion of the upper jig 110 such that a second end of the pusher housing 130 can rotate upwards or downwards. The lift panel 140 is installed below the pusher housing 130 so as to be elastically movable upwards or downwards. The pressing panel 150 is installed below the pusher housing 130 so as to be linearly movable to the left or the right and moves the lift panel 140 upwards or downwards. The lift means makes the upward or downward movement of the lift panel 140 possible. The pusher block 160 is installed below the lift panel 140 and has pushers 162 which are provided at positions corresponding to the respective package seating holes 112 and press the corresponding memory packages 50. The harsh-thermal-environment creating unit 170 is installed on an upper side of the pusher block 160 and generates or absorbs heat to provide harsh thermal conditions to the memory packages 50. The cooling unit 180 performs cooling operation when the harsh-thermal-environment creating unit 170 generates or absorbs heat. The lift lever 190 is installed at a predetermined position on the pusher housing 130 and rotates to the left or the right so as to linearly move the pressing panel 150 to the left or the right.

As mentioned above, the memory package test jig 100 according to the present invention includes the upper and lower jigs 110 and 120 which respectively support upper and lower sides of the socket board 10, the pusher housing 130, the lift panel 140, the pressing panel 150, the lift means, the pusher block 160, the harsh-thermal-environment creating unit 170, the cooling unit 180 and the lift lever 190. The memory package test jig 100 electrically connects the memory packages 50 seated in the respective package seating holes 112 formed in the upper jig 110 to the sockets 12 so as to test the memory packages 50 for defects.

During a process of testing the memory packages 50 for defects by means of determining whether the memory packages 50 seated in the respective package seating holes 112 formed in the upper jig 110 are correctly electrically connected to the sockets 12, the harsh-thermal-environment creating unit 170 provides a harsh thermal environment of low or high temperature conditions to the memory packages 50 via the pushers 162, thus making it possible to obtain more thermally reliable memory packages 50.

The elements constituting the memory package test jig 100 according to the present invention will be explained in more detail below. The upper jig 110 functions to fix the socket board 10 in a place in cooperation with the lower jig 120 which will be explained later herein. As shown in FIGS. 1, 3, 5, 8A and 8B, the upper jig 110 has package seating holes 112 which are vertically formed in the upper jig 110 at positions corresponding to the respective sockets 12 mounted on a socket board 10, and into which the memory packages 50 are respectively seated.

While the memory packages 50 are not mounted the respective sockets 12 of the socket board 10 which is available commercially, the upper jig 110 fixes the socket board 10 in a place between it and the lower jig 120. That is, the socket board 10 is positioned between the upper jig 110 and the lower jig 120 which are respectively disposed at upper and lower positions, and is fixed in a place by the upper jig 110 and the lower jig 120 which are coupled to each other by a binding screw.

The package seating holes 112 into which the memory packages 50 to be tested for defects are respectively seated are vertically formed in the upper jig 110 at positions corresponding to the respective sockets 12 mounted on a socket board 10. Electrically connected to contact points of each socket 12, a connection board 20 is fixed between an upper side of the socket 12 of the socket board 10 which is interposed between the upper jig 110 and the lower jig 120 and a lower end of the corresponding package seating hole 112 of the upper jig 110.

Therefore, when testing the memory packages 50 for defects using the memory package test jig 100 according to the present invention, the memory packages 50 which are seated in the respective package seating holes 112 of the upper jig 110 are tested for defects by determining whether the memory packages 50 are electrically connected to corresponding contact terminals of the connection board 20 when the pusher 162 presses the memory packages 50.

The lower jig 120 functions to fix the socket board 10 in a place between it and the upper jig 110. As shown in FIGS. 1, 3, 5, 8A and 8B, an upper side of the lower jig 120 has a shape corresponding to a lower side of the socket board 10 which is a target to be fixed, whereby the socket board 10 can be reliably fixed in a place between the lower jig 120 and the upper jig 110.

A lower side of the lower jig 120 is planar such that the lower jig 120 which fixes the socket board 10 between it and the upper jig 110 can be placed on the bottom of a space for testing the memory package 50.

The pusher housing 130 covers an upper side of the upper jig 110. As shown in FIGS. 1, 4A, 4B, 5, 8A and 8B, the pusher housing 130 is hinged at the first end thereof to the first end of the upper portion of the upper jig 110 such that the second end of the pusher housing 130 can rotate upwards or downwards.

A retaining hook 132 is provided on the second end of the pusher housing 130 which is hinged at the first end thereof to the upper portion of the upper jig 110 such that the second end of the pusher housing 130 can rotate upwards or downwards. Thus, the pusher housing 130 can be elastically locked to the upper jig 110 by the retaining hook 132. The retaining hook 132 is hooked in a locking depression 114 which is formed in a second end of the upper jig 110.

The lift panel 140 is configured to be movable upwards or downwards. As shown in FIGS. 1, 4a, 4b, 6a, 6b, 7A, 7B, 8A and 8B, the lift panel 140 is installed below the pusher housing 130 so as to be elastically movable upwards or downwards.

In detail, both ends of the lift panel 140 are supported by elastic springs 142 so that the lift panel 140 can elastically move upwards or downwards. The upward or downward movement of the lift panel 140 is embodied by interaction among the lift lever 190, the pressing panel 150 and the lift means.

The pressing panel 150 presses the lift panel 140 or releases it to move the lift panel 140 downwards or upwards. As shown in FIGS. 1, 4A, 4B, 6A, 6B, 7A, 7B, 8A and 8B, the pressing panel 150 is installed below the pusher housing 130 so as to be linearly movable to the left or the right and moves the lift panel 140 upwards or downwards.

That is, the pressing panel 150 is installed between the pusher housing 130 and the lift panel 140 so as to be linearly movable to the left or the right. When the lift lever 190 rotates, the pressing panel 150 linearly moves to the left or the right, thus moving the lift panel 140 upwards or downwards.

The lift means functions to make it possible for the lift panel 140 to be moved upwards or downwards when the pressing panel 150 is linearly moved to the left or the right by rotating the lift lever 190. AS shown in FIGS. 4A, 4B, 6A, 6B, 7A, 7B, 8A, and 8B, the lift means includes rollers 152 and lift guides 144. Each roller 152 is rotatably installed in the pressing panel 150 in such a way that a portion of the roller 152 protrudes downwards from the lower side of the pressing panel 150. Each lift guide 144 includes an inclined side 144a and a horizontal side 144b. The inclined side 144a is formed on an upper side of the lift panel 140 and inclined upwards in a direction with a length corresponding to a range of movement of the roller 152 that depends on the linear left or right movement of the pressing panel 150. The horizontal side 144b is formed on the top of the inclined side.

The lift means having the above-mentioned construction is operated in such a way that when the pressing panel 150 is linearly moved to the left or right by rotating the lift lever 190, the rollers 152 which protrude downwards from the lower side of the pressing panel 150 move upwards and downwards along the inclined sides 144a and the horizontal sides 144b of the corresponding lift guides 144 which are formed on the upper side of the lift panel 140.

That is, in the above-mentioned operation, the pressing panel 150 is linearly moved to the right by turning the lift lever 190 to the left. When the pressing panel 150 linearly moves to the right, each roller 152 moves up onto the horizontal side 144b via the inclined side 144a of the corresponding lift guide 144, so that the lift panel 140 moves downwards by the height of the horizontal side 144b.

As mentioned above, when the lift panel 140 is moved downwards by the operation of the lift means in response to the right movement of the pressing panel 150, the pushers 162 which are provided under the lower side of the pusher block 160 moves downwards. As a result, the memory packages 50 that are seated in the package seating holes 112 of the upper jig 110 are pressed by the pushers 162 onto the corresponding sockets 12 which are mounted on the socket board 10.

Each memory package 50 which is pressed by the corresponding pusher 162 is electrically connected to the associated socket 12 by means of connection to the connection board 20 which is provided between the upper side of the corresponding socket 12 of the socket board 10 and a lower end of the associated package seating hole 112 of the upper jig 110. Here, whether the memory package 50 is defective is determined depending on whether the electrical connection is made or not.

Meanwhile, in the above-mentioned construction of the lift means, after the test for the memory package 50 has been completed, when the pressing panel 150 is linearly moved to the left by turning the lift lever 190 to the right, the rollers 152 move from the horizontal sides 144b of the lift guides 144 along the inclined sides 144a to the lowermost portions of the guides 144. During this process, the lift panel 140 is moved upwards by the restoring force of the elastic springs 142.

As such, as the rollers 152 move from the horizontal sides 144b of the lift guides 144 to the lowermost portions of the guides 144 along the inclined sides 144a, when the lift panel 140 is moved upwards by the restoring force of the elastic springs 142, the memory packages 50 that have been pressed by the pushers 162 are released therefrom. In this state, the pusher housing 130 is opened and the memory packages 50 are removed from the package seating holes 112 of the upper jig 110. Then, the test for the memory packages 50 is finished.

In brief, in the interaction among the pressing panel 150, the lift means and the lift panel 140, if the rollers 152 are moved upwards to the horizontal sides 144b along the inclined sides 144a of the lift guides 144 by linear movement of the pressing panel 150 in a direction, the lift panel 140 is pressured by the rollers 152, thus moving downwards. On the other hand, if the rollers 152 are moved downwards from the horizontal sides 144b of the lift guides 144 to the lowermost portions of the lift guides 144 along the inclined sides 144a by linear movement of the pressing panel 150 in the other direction, the lift panel 140 that has been pressed by the rollers 152 is released therefrom, thus moving upwards.

The pusher block 160 transfers heat from the harsh-thermal-environment creating unit 170 to the memory packages 50 through the pushers 162. As shown in FIGS. 1, 2, 7A, 7B, 8A and 8B, the pusher block 160 is installed below the lift panel 140 and has on a lower side thereof the pushers 162 which are provided at positions corresponding to the respective package seating holes 112 and press the corresponding memory packages 50.

When the harsh-thermal-environment creating unit 170 which is installed on an upper side of the pusher block 160 generates or absorbs heat, the pusher block 160 transfers heat to the pushers 162 or absorbs heat from the pushers 162 so as to transfer heat to the memory packages 50 or absorb heat from the memory packages 50 that are respectively seated into the package seating holes 112 of the upper jig 110. Thereby, harsh thermal conditions are applied to the memory packages 50. That is, the pusher block 160 functions to transmit heat from the harsh-thermal-environment creating unit 170 to the memory packages 50 or absorb heat from the memory packages 50.

As mentioned above, the pusher block 160, which transfers heat from the harsh-thermal-environment creating unit 170 to the memory packages 50 through the pushers 162 or absorbs heat from memory packages 50 through the pushers 162 so as to provide harsh thermal conditions to the memory packages 50, is configured in such a way that unit blocks each of which has a shape corresponding to the associated package seating hole 112 formed in the upper jig 110 are integrated with each other. The pushers 162 are vertically-elastically coupled to lower sides of the respective unit blocks.

The harsh-thermal-environment creating unit 170 generates or absorbs heat by application of constant voltage or inverse voltage. As shown in FIGS. 1, 2, 7A, 7B, 8A and 8B, the harsh-thermal-environment creating unit 170 which is installed on the upper side of the pusher block 160 generates or absorbs heat so that heat is transferred to or absorbed from the memory packages 50 through the pusher block 160 and the pushers 162, thus providing harsh thermal conditions to the memory packages 50.

The harsh-thermal-environment creating unit 170 includes an element protection block 172 and peltier elements 174. The element protection block 172 has a shape corresponding to the pusher block 160 and includes a plurality of element seating parts 172a which are configured to correspond to the respective pushers 162. The peltier elements 174 are installed in the respective element seating parts 172a of the element protection block 172 and generate or absorb heat by means of voltage applied thereto so as to provide harsh thermal conditions of a high or low temperature to the memory packages 50 seated in the package seating holes 112 through the pusher block 160 and the pushers 162.

In the above-mentioned construction of the harsh-thermal-environment creating unit 170, each peltier element 174 is a device which has a thin plate shape, and in which both sides thereof respectively function to a heat absorbing unit and a heat generating unit. When voltage is applied to the peltier element 174, the heat absorbing unit absorbs surrounding heat such that the temperature thereof reduces to the room temperature or less (generally below zero), while heat and consumed electrical energy of the heat absorbing unit is emitted to the outside of the peltier element 174 through the heat generating unit whereby the temperature of the heat generating unit increases to 100° C. or more.

The principle of the peltier element 174 is opposed to that of thermal difference generation. In detail, the peltier element uses a principle in which when electricity is applied to N-type and P-type semiconductors that are bonded to each other, free electrons are moved to positive holes. When free electrons of the P-type semiconductor are moved to positive holes of the N-type semiconductor, even if each free electron has a little heat, the P-type semiconductor losses a lot of heat energy, while the N-type semiconductor receives a lot of heat.

However, if heat generated from the peltier element 174 exceeds the capacity thereof, both the heat absorbing unit and the heat generating unit begin to be heated. Figuratively, this is like a pump which pumps water out of one of two rooms and supplies it into the other room. No matter how superior the performance of the pump, if a total amount of water is greatly increased, there is no alternative but for the water levels of the two rooms to both increase.

Therefore, in order to enable the heat absorbing unit of the peltier element 174 to exhibit satisfactory cooling performance, it is very important to reliably dissipate heat generated from the heat generating unit. If heat generated from the heat generating unit can be reliably dissipated, the peltier element can be importantly used to control the temperature of an electronic product. The reason for this is because of the fact that although these days the term “water cooling” means using only water, just a few years ago a water cooling type cooler was configured such that the peltier element cools a CPU and water is used to cool the heat generating unit of the peltier element 174.

As mentioned above, in the harsh-thermal-environment creating unit 170 according to this embodiment, when positive voltage or reverse voltage is applied to the peltier element 174, one side of the peltier element 174 generates or absorbs heat, whereby harsh thermal conditions of a high or low temperature are provided to the corresponding memory package 50 through the pusher block 160 and the pusher 162.

In this embodiment, in harsh thermal conditions created by the harsh-thermal-environment creating unit 170, the temperature of the low-temperature harsh thermal environment ranges from −30° C. to 5° C., and the temperature of the high-temperature harsh thermal environment ranges from 60° C. to 130° C.

The cooling unit 180 cools the heat generating units of the peltier elements 174. As shown in FIGS. 1, 2, 7A, 7B, 8A and 8B, the cooling unit 180 dissipates heat generated from the heat generating units of the peltier elements 174 of the harsh-thermal-environment creating unit 170, thus preventing the heat absorbing units and the heat generating units from being heated together.

The cooling unit 180 includes a water cooling block 182, a watertight cover 184 and cooling water inlet and outlet valves 186. The water cooling block 182 is installed above the element protection block 172 after the peltier elements 174 have been seated on the respective element seating parts 172a of the element protection block 172. The water cooling block 182 has on an upper side thereof a cooling water flow passage 182 along which cooling water flows. The watertight cover 184 covers an upper side of the water cooling block 182 to prevent the cooling water that flows along the cooling water flow passage 182a from leaking. The cooling water inlet and outlet valves 186 are installed at predetermined positions on an upper side of the watertight cover 184 so that cooling water supplied from a cooling water supply source is drawn into an inlet of the cooling water flow passage 182a through the cooling water inlet valve 186 and cooling water is discharged from an outlet of the cooling water flow passage 182a through the cooling water outlet valve 186.

Meanwhile, the water cooling block 182 of the cooling unit 180 is brought into close contact with the upper side of the element protection block 172 on which the peltier elements 174 have been seated. Cooling water circulates through the cooling water flow passage 182a of the water cooling block 182, thus dissipating heat generated from the heat generating units of the peltier elements 174, thereby preventing the heat absorbing units and the heat generating units from being heated together.

In the above-mentioned construction of the cooling unit 180, the water cooling block 182 provided with the watertight cover 184 on an upper side thereof is fastened to a lower side of the lift panel 140.

Also, the cooling water inlet and outlet valves 186 of the cooling unit 180 are vertically installed on the upper side of the watertight cover 184 at positions corresponding to the inlet and the outlet of the cooling water flow passage 182a. The cooling water inlet and outlet valves 186 are exposed to the outside from the upper side of the pusher housing 130 through a through hole 134 which is vertically formed in the pusher housing 130 at a position corresponding to the cooling water inlet and outlet valves 186. The exposed inlet and outlet valves 186 are connected to the cooling water supply source by cooling water hoses.

The lift lever 190 linearly moves the pressing panel 150 to the left or right so as to move the lift panel 140 upwards and downwards. As shown in FIGS. 1, 4A, 4B, 5, 6A, 6B, 7A and 7B, the lift lever 190 is installed on a portion of the lift panel 140 so as to be rotatable to the left or right within a predetermined range and is configured such that when it rotates to the left or right, the pressing panel 150 can be linearly moved to the left or right.

In detail, the lift lever 190 has in a first end thereof a link slot 192 into which a shaft protrusion 154 provided under a predetermined portion of the lower side of the pressing panel 150 is inserted. Furthermore, corresponding to a hinge shaft 146 which is provided on a predetermined portion of the lift panel 140, a hinge hole 194 is formed in the first end of the lift lever 190 at a position adjacent to the link slot 192. In the lift lever 190 having the above-mentioned structure, when a second end of the lift lever 190 rotates on the hinge shaft 146 to the left or right by a predetermined angle, the pressing panel 150 is linearly moved to the left or the right to move the lift panel 140 upwards or downwards.

The memory package test jig according to the prevent invention having the above-mentioned construction further includes a finishing cover 200 which is disposed under the pusher block 160 and is coupled to a lower end of the pusher housing 130. The finishing cover 200 has therein a pusher passing opening 202 through which the pushers 162 pass upwards or downwards.

The finishing cover 200 functions to cover the lower end of the pusher housing 130. As shown in FIGS. 1, 2 and 8, having the pusher passing opening 202 through which the pushers 162 pass upwards or downwards, the finishing cover 200 is disposed under the pusher block 160 and is coupled to the lower end of the pusher housing 130.

Particularly, the finishing cover 200 disposed under the block 160 is coupled to the lower end of the pusher housing 130 in such a way that the pusher block 160, the element protection block 172, the water cooling block 182, the watertight cover 184, the lift panel 140 and the pressing panel 150 are arranged in a positional order from the bottom to the top between a lower side of the pusher housing 130 and the finishing cover 200.

When the lift panel 140 is moved upwards or downwards by the left or right linear movement of the pressing panel 150, the pushers 162 pass upwards or downwards through the pusher passing opening 202 of the finishing cover 200.

As shown in FIGS. 1 and 5, the memory package test jig according to the prevent invention having the above-mentioned construction further includes a cooling fan 210 which is provided at a predetermined position on the upper side of the upper jig 110. While the memory packages 50 are tested for defects by determining whether the memory packages 50 are electrically connected to the corresponding sockets 12 mounted on the socket board 10 fixed between the upper jig 110 and the lower jig 120, the fooling fan 210 discharges air heated by heat generated from the socket board 10 to the outside air, thus preventing the socket board 10 from overheating.

The cooling fan 210 is installed in a through hole which is vertically formed at a predetermined position in the upper jig 110. The cooling fan 210 discharges air that is between the upper jig 110 and the lower jig 120 to the outside so as to dissipate heat generated from the socket board 10, thus preventing the socket board 10 from overheating, thereby making it possible for the test to be reliably performed.

As shown in FIGS. 1 and 4B, the memory package test jig according to the prevent invention having the above-mentioned construction further includes a housing-side shock absorber 220 which has an elastic structure and is provided at a predetermined position under the lower side of the pusher housing 130. The housing-side shock absorber 220 absorbs, using elasticity thereof, shock generated when the pusher housing 130 rotates downwards and the lower side thereof comes into contact with the upper side of the upper jig 110 and while the close contact between the pusher housing 130 and the upper jig 110 is maintained by the retaining hook 132 provided on the second end of the pusher housing 130.

As shown in FIG. 1, the memory package test jig further includes a jig-side shock absorber 222 which has an elastic structure and is provided at a predetermined position on the upper side of the upper jig 110. The jig-side shock absorber 222 elastically supports the pusher housing 130 when the pusher housing 130 rotates downwards and the lower side thereof comes into contact with the upper side of the upper jig 110.

As such, when the pusher housing 130 rotates onto the upper jig 110 and covers the upper side of the upper jig 110, the housing-side shock absorber 220 and the jig-side shock absorber 222 absorb shock generated when the pusher housing 130 makes contact with the upper jig 110 and elastically support the pusher housing 130. In detail, the housing-side shock absorber 220 elastically supports the upper side of the upper jig 110, while the jig-side shock absorber 222 elastically supports the lower side of the pusher housing 130.

As shown in FIGS. 1 and 3, the memory package test jig according to the present invention further includes a dry air supply means 230 which supplies dry air to the package seating holes 112 to prevent dew condensation from being caused by a temperature difference when the peltier elements 174 generate or absorb heat. That is, the dry air supply means 230 supplies dry air onto the upper side of the socket board 10 between the upper jig 110 and the lower jig 120, thus preventing dew condensation from being caused not only on the sockets 12 but also on the connection board 20, the package seating holes 112, the memory packages 50, etc.

In detail, the dry air supply means 230 includes a plurality of dry air supply passages 232 and dry air supply valves 234. The dry air supply passages 232 are horizontally formed in a side of the upper jig 110 to predetermined depths at positions adjacent to the package seating holes 112. Each dry air supply passage 232 is open downwards at an outlet thereof. The dry air supply valves 234 are coupled to inlets of the respective dry air supply passages 232 so that dry air can be supplied from a dry air supply source into spaces that are adjacent to the package seating holes 112 between the lower side of the upper jig 110 and the upper side of the socket board 10.

In the dry air supply means 230 having the above-mentioned construction, if dry air is supplied into the dry air supply passages 232 through the dry air supply valves 234 connected to the dry air supply source, the dry air is discharged onto the socket board 10 between the upper jig 10 and the lower jig 120 via the dry air supply passage 232. The discharged dry air is dispersed in all directions on the upper side of the socket boar 10 and is thus supplied not only to the sockets 12 but also to the connection board 20, the package seating holes 112, the memory packages 50, etc., thus preventing dew condensation from being caused by a temperature difference when the peltier elements 174 generate or absorb heat.

As described above, in the technique according to the present invention, when the pressing panel 150 is linearly moved in a direction by rotating the lift lever 190 in a direction, the lift panel 140 is moved downwards by the operation of the lift means. Then, coupled to the lower side of the left panel 140 in a consecutive order, the watertight cover 184, the water cooling block 182, the element protection block 172 and the pusher block 160 are moved downwards along with the lift panel 140.

If the lift panel 140 is moved downwards, the pushers 162 provided under the pusher block 160 press the corresponding memory packages 50 that are seated in the respective package seating holes 112 of the upper jig 110. In this state, the memory packages 50 are tested for defects by determining whether the memory packages 50 are correctly electrically connected to the sockets 12 that are mounted to the socket board 10 by the connection boards 20.

Meanwhile, during the process of testing the memory packages 50 for defects by pressing the memory packages 50 seated in the respective package seating holes 112 of the upper jig 110 and determining whether the memory packages 50 are correctly electrically connected to the sockets 12 that are mounted to the socket board 10 by the connection boards 20, the harsh-thermal-environment creating unit 170 provides a harsh thermal environment of low or high temperature conditions to the memory packages 50 via the pushers 162, thus making it possible to obtain more thermally reliable memory packages 50.

Therefore, the technique according to the present invention having the above-mentioned construction is very useful in that more thermally reliable memory packages can be obtained by means of testing thermal limit characteristics of the memory packages.

Although the preferred embodiment of the present invention has been disclosed for illustrative purposes, those skilled in the art will appreciate that various modifications, additions and substitutions are possible, without departing from the scope and spirit of the invention as disclosed in the accompanying claims.

1. A memory package test jig having a harsh condition creating structure, comprising:
an upper jig with a plurality of package seating holes vertically formed in the upper jig at positions corresponding to respective sockets mounted on a socket board, wherein memory packages are respectively seated into the package seating holes;
a lower jig fixing the socket board between the lower jig and the upper jig;
a pusher housing hinged at a first end thereof to an upper side of the upper jig such that a second end of the pusher housing is movable upwards or downwards;
a lift panel provided below the pusher housing so as to be elastically movable upwards or downwards;
a pressing panel provided under the pusher housing so as to be linearly movable to leftwards or rightwards, the pressing panel moving the lift panel upwards or downwards;
a lift means provided to enable the upward or downward movement of the lift panel;
a pusher block provided below the lift panel, the pusher blocking comprising pushers provided corresponding to the respective package seating holes, the pushers pressing the corresponding memory packages;
a harsh-thermal-environment creating unit provided on an upper side of the pusher block, the harsh-thermal-environment creating unit generating or absorbing heat to provide harsh thermal conditions to the memory packages;
a cooling unit conducting a cooling operation when the harsh-thermal-environment creating unit generates or absorbs heat; and
a lift lever provided to an end of the lift panel, the lift lever rotating leftwards or rightwards so as to linearly move the pressing panel leftwards or rightwards.

2. The memory package test jig as set forth in claim 1, wherein the lift means comprises:
a plurality of rollers rotatably provided in the pressing panel in such a way that a portion of each roller is protruded from a side of the pressing panel; and
a plurality of lift guides, each lift guide comprising: an inclined side formed on an upper side of the lift panel and a horizontal side formed on a top of the inclined side corresponding to a range of movement of the roller corresponding to the linear left or right movement of the pressing panel.

3. The memory package test jig as set forth in claim 2, wherein when the rollers are moved upwards to the horizontal sides along the inclined sides of the lift guides by linearly moving the pressing panel in one direction, the lift panel is pressured by the rollers and moved downwards, and when the rollers are moved downwards from the horizontal sides of the lift guides to lowermost portions of the lift guides along the inclined sides by linearly moving the pressing panel in the other direction, the lift panel is released from the pressure of the rollers and moved upwards.

4. The memory package test jig as set forth in claim 1, wherein the harsh-thermal-environment creating unit comprises:
an element protection block having a shape corresponding to the pusher block, the element protection block comprising a plurality of element seating parts configured to correspond to the respective pushers; and
a plurality of peltier elements provided in the respective element seating parts of the element protection block, the peltier elements generating or absorbing heat by voltage applied thereto so as to provide harsh thermal conditions of a high or low temperature to the corresponding memory packages through the pusher block and the pushers.

5. The memory package test jig as set forth in claim 4, wherein the voltage applied to the peltier elements of the harsh-thermal-environment creating unit is positive voltage or negative voltage, whereby one side of the peltier element generates or absorbs heat, thus providing harsh thermal conditions of a high or low temperature to the corresponding memory package through the pusher block and the pusher.

6. The memory package test jig as set forth in claim 5, wherein the harsh thermal conditions created by the harsh-thermal-environment creating unit comprise low-temperature harsh environment conditions ranging in temperature from −30° C. to 5° C., and high-temperature harsh environment conditions ranging in temperature from 60° C. to 130° C.

7. The memory package test jig as set forth in claim 5, wherein the cooling unit comprises:
a water cooling block provided above the element protection block with the peltier elements seated on the respective element seating parts of the element protection block, the water cooling block having on an upper side thereof a cooling water flow passage along which cooling water flows;
a watertight cover covering the upper side of the water cooling block to prevent the cooling water flowing along the cooling water flow passage from leaking; and
a cooling water inlet valve and a cooling water outlet valve provided to an upper side of the watertight cover so that cooling water supplied from a cooling water supply source is drawn into an inlet of the cooling water flow passage through the cooling water inlet, or from an outlet of the cooling water flow passage through the cooling water outlet valve.

8. The memory package test jig as set forth in claim 7, wherein the water cooling block is fastened to a lower side of the lift panel with the watertight cover installed on the upper side of the water cooling block.

9. The memory package test jig as set forth in claim 8, wherein the cooling water inlet valve and the cooling water outlet valve of the cooling unit are vertically provided on the upper side of the watertight cover corresponding to the inlet and the outlet of the cooling water flow passage in such a way that the cooling water inlet valve and the cooling water outlet valve are exposed from the upper side of the pusher housing through a through hole, the through hole being vertically formed in the pusher housing corresponding to the cooling water inlet valve and the cooling water outlet valve.

10. The memory package test jig as set forth in claim 1, further comprising
a finishing cover disposed under the pusher block and coupled to a lower end of the pusher housing, the finishing cover having therein a pusher passing opening through which the pushers pass upwards or downwards.

11. The memory package test jig as set forth in claim 10, further comprising
a cooling fan provided to the upper side of the upper jig so that while the memory packages are tested for defects through the electrical connection between the memory packages and to the corresponding sockets mounted on the socket board fixed between the upper jig and the lower jig, the cooling fan discharges heat generated from the socket board to the outside, thus preventing the socket board from overheating.

12. The memory package test jig as set forth in claim 11, further comprising
a housing-side shock absorber elastically provided under a lower side of the pusher housing, the housing-side shock absorber absorbing shock generated when the pusher housing rotates downwards and a lower side thereof comes into contact with the upper side of the upper jig and while the close contact between the pusher housing and the upper jig is maintained by a retaining hook provided to an end of the pusher housing.

13. The memory package test jig as set forth in claim 10, further comprising
a jig-side shock absorber elastically provided to the upper side of the upper jig, the jig-side shock absorber absorbing shock generated when the pusher housing rotates downwards and a lower side thereof comes into contact with the upper side of the upper jig and while the close contact between the pusher housing and the upper jig is maintained by a retaining hook provided to an end of the pusher housing.

14. The memory package test jig as set forth in claim 10, further comprising
a dry air supply means supplying dry air to the package seating holes to prevent dew condensation from being caused by a temperature difference when the peltier elements generate or absorb heat.

15. The memory package test jig as set forth in claim 14, wherein the dry air supply means comprises:
a plurality of dry air supply passages horizontally formed in a side of the upper jig to predetermined depths adjacent to the package seating holes, each of the dry air supply passage being open downwards; and
a dry air supply valve coupled to an inlet of each of the dry air supply passages so that dry air from a dry air supply source is supplied into a space adjacent to the corresponding package seating hole between a lower side of the upper jig and an upper side of the socket board.
